(19) United States
(12) Patent Application Publication
(10) Pub. No.: US 2013/0118547 A1
(43) Pub. Date: May 16, 2013

(54) PHOTOVOLTAIC WINDOW WITH LIGHT-TURNING FEATURES

(71) Applicants: Russell W. Gruhlke, Milpitas, CA (US); Ye Yin, Santa Clara, CA (US); Fan Yang, Sunnyvale, CA (US); Sijin Han, Milpitas, CA (US)

(72) Inventors: Russell W. Gruhlke, Milpitas, CA (US); Ye Yin, Santa Clara, CA (US); Fan Yang, Sunnyvale, CA (US); Sijin Han, Milpitas, CA (US)

(73) Assignee: QUACLOMM MEMS Technologies, Inc., San Diego, CA (US)

(21) Appl. No.: 13/294,907

(22) Filed: Nov. 11, 2011

(51) Int. Cl. H01L 31/052; H01L 31/18

(52) U.S. Cl. 136/246; 136/259; 438/65; 257/E31.127

(57) ABSTRACT

This disclosure provides systems, methods, and apparatus for directing light incident on a window towards photovoltaic cells. In one aspect, photovoltaic cells are arranged the perimeter of a window pane. The pane also includes light-turning features that divert a portion of the incident light towards the photovoltaic cells on the perimeter, while simultaneously transmitting a portion of incident light through the pane. The dimensions and arrangement of the light-turning features can be adjusted to change the amount of light diverted to the photovoltaic cells, and consequently the amount of light transmitted through the glass.

### TECHNICAL FIELD

This disclosure relates generally to the field of optoelectronic devices that convert optical energy into electrical energy, for example, photovoltaic devices.

### DESCRIPTION OF THE RELATED TECHNOLOGY

For over a century fossil fuel such as coal, oil, and natural gas has provided the main source of energy in the United States. The need for alternative sources of energy is increasing. Fossil fuels are a non-renewable source of energy that is depleting rapidly. The large scale industrialization of developing nations such as India and China has placed a considerable burden on the availability of fossil fuel. In addition, geopolitical issues can quickly affect the supply of such fuel. Global warming is also of greater concern in recent years. A number of factors are thought to contribute to global warming; however, widespread use of fossil fuels is considered to be a main cause of global warming. Thus there is an urgent need to find a renewable and economically viable source of energy that is also environmentally safe. Solar energy is an environmentally friendly renewable source of energy that can be converted into other forms of energy such as heat and electricity.

Photovoltaic cells convert optical energy to electrical energy and thus can be used to convert solar energy into electrical power. Photovoltaic solar cells can be made very thin and modular. Photovoltaic cells can range in size from a about few millimeters to tens of centimeters, or larger. The individual electrical output from one photovoltaic cell may range from a few milliwatts to a few watts. Several photovoltaic cells may be connected electrically and packaged in arrays to produce a sufficient amount of electricity. Photovoltaic cells can be used in a wide range of applications such as providing power to satellites and other spacecraft, providing electricity to residential and commercial properties, charging automobile batteries, etc.

While photovoltaic devices have the potential to reduce reliance upon fossil fuels, the widespread use of photovoltaic devices has been hindered by inefficiency concerns and concerns regarding the material costs required to produce such devices. Additionally, traditional photovoltaic devices are often considered bulky and unattractive. Accordingly, improvements in design, efficiency and/or manufacturing could increase usage of photovoltaic devices.

### SUMMARY

The systems, methods and devices of the disclosure each have several innovative aspects, no single one of which is solely responsible for the desirable attributes disclosed herein.

One innovative aspect of the subject matter described in this disclosure can be implemented in window including an at least partially transmissive pane, the pane including a surface for receiving incident light, a plurality of photovoltaic cells arranged around the perimeter of the partially transmissive pane, and a plurality of light-turning features, coupled to the pane, configured to direct a portion of light incident on the surface of the pane towards at least one of the photovoltaic cells. In one implementation, the light-turning features can include frustum-shaped features arranged on the light-receiving surface of the pane, with each frustum-shaped feature including a first surface and a second surface disposed substantially parallel to the first surface, the first surface having a smaller area dimension than the second surface, with the first surface disposed on the light-receiving surface of the pane. A width dimension at the widest portion of each frustum-shaped feature may be between about 1 μm and about 10 mm, and a height dimension of each frustum-shaped feature may be between about 1 μm and about 5 mm. In another implementation, the light-turning features can include frustum-shaped cavities in the pane, with a portion of the pane defining each of the frustum-shaped cavities including a first surface and a second surface disposed substantially parallel to the first surface and on an opposite side of the cavity from the first surface, the first surface having a smaller area dimension than the second surface, and wherein the first surface is disposed substantially parallel to the light-receiving surface and closer to the light-receiving surface than the second surface. A width dimension at the widest portion of each frustum-shaped cavity may be between about 1 μm and about 10 mm, and a height dimension of each frustum-shaped cavity may be between about 1 μm and about 5 mm. The frustum-shaped cavities may be arranged in two or more layers within the partially transmissive pane, each layer being at a different distance from the light-receiving surface of the pane. In another implementation, the light-turning features can be further configured to permit at least 20% of the incident light to pass through the partially transmissive pane. In another implementation the pane may be characterized by a width dimension and a length dimension, each between about 0.3 m and about 3 m. In another implementation, the pane can be characterized by a thickness dimension of between about 5 mm and about 5 cm. In another implementation, the window may be configured to direct light to propagate within the partially transmissive pane towards the plurality of photovoltaic cells by total internal reflection. In another implementation, the pane can include glass.

In another aspect, a power generating system includes a plurality of windows arranged in an array, each window including an at least partially transmissive pane including a surface for receiving incident light, a plurality of photovoltaic cells arranged around the perimeter of the partially transmissive pane, and a plurality of frustum-shaped light-turning features, coupled to the pane, configured to direct light incident on the surface of the pane towards the plurality of photovoltaic cells. In one implementation, each of the plurality of frustum-shaped light-turning features may include a first surface and a second surface disposed substantially parallel to the first surface, the first surface having a smaller area dimension than the second surface, the first surface disposed on the light-receiving surface of the pane. In another implementation, each of the plurality of frustum-shaped light-turning features may include a frustum-shaped cavity in the pane, with a portion of the pane defining each of the frustum-shaped cavities including a first surface and a second surface disposed substantially parallel to the first surface and on an opposite side of the cavity from the first surface, the first surface having a smaller area dimension than the second surface, the first surface disposed substantially parallel to the light-receiving surface and closer to the light-receiving surface than the second surface.

In another aspect, a window includes a substantially transparent pane, the pane including a surface for receiving incident light, means for generating electrical power from light, the power generating means arranged around the perimeter of the pane, and means for redirecting a portion of light received on the light-receiving surface towards the power generating means. In one implementation, the power generating means may include a photovoltaic cell. In another implementation, the redirecting means may include frustum-shaped features arranged on the light-receiving surface of the pane, with each frustum-shaped feature including a first surface and a second surface disposed substantially parallel to the first surface, the first surface having a smaller area dimension than the second surface, the first surface disposed on the light-receiving surface of the pane. In another implementation, the redirecting means may include frustum-shaped cavities in the pane, with a portion of the pane defining each of the frustum-shaped cavities including a first surface and a second surface disposed substantially parallel to the first surface and on an opposite side of the cavity from the first surface, the first surface having a smaller area dimension than the second surface, with the first surface disposed substantially parallel to the light-receiving surface and closer to the light-receiving surface than the second surface.

In another aspect, a method of manufacturing a window includes providing a partially transmissive pane, the pane including a surface for receiving light, disposing a plurality of photovoltaic cells around the perimeter of the pane, and providing a plurality of frustum-shaped light-turning features configured to direct a portion of light incident on a surface of the pane towards the photovoltaic cells. In one implementation, providing the plurality of light-turning features may include forming a plurality of frustum-shaped features on the light-receiving surface of the pane, with each frustum-shaped feature including a first surface and a second surface disposed substantially parallel to the first surface, the first surface having a smaller area dimension than the second surface, and with the first surfaces disposed on the light-receiving surface of the pane. In another implementation, providing the plurality of light-turning features may include forming a plurality of frustum-shaped cavities within the pane, with a portion of the pane defining each of the frustum-shaped cavities. The frustum-shaped cavities can each include a first surface and a second surface disposed substantially parallel to the first surface and on an opposite side of the cavity from the first surface, the first surface having a smaller area dimension than the second surface, the first surface disposed substantially parallel to the light-receiving surface and closer to the light-receiving surface than the second surface. Forming the plurality of frustum-shaped cavities within the partially transmissive pane can further include forming a first subset of the plurality of frustum-shaped cavities on a first layer within the partially transmissive pane, and forming a second subset of the plurality of frustum-shaped cavities on a second layer within the partially transmissive pane, with the first and the second layers at different distances from the light-receiving surface of the partially transmissive pane. Forming the first subset of the plurality of frustum-shaped cavities can include forming recesses in a first glass panel and bonding a second glass panel over the first glass panel to form frustum-shaped cavities therein. Likewise, forming the second subset of the plurality of frustum-shaped cavities can include forming recesses in the second glass panel and bonding a third glass panel over the second glass panel to form frustum-shaped cavities therein. In some implementations, the recesses can be formed in the second glass panel before it is bonded over the first glass panel. In other implementations, the recesses can be formed in the second glass panel after it is bonded over the first glass panel.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

The invention and various embodiments and features may be better understood by reference to the following drawings in which:

FIG. 1A is an example of a cross-section of one implementation of a photovoltaic cell including a p-n junction.

FIG. 1B is an example of a block diagram that schematically illustrates a cross-section of one example of a photovoltaic cell including a deposited thin film photovoltaic active material.

FIG. 2A is an example of a schematic plan view of a photovoltaic window.

FIG. 2B is an example of a schematic plan view of a tiled photovoltaic window.

FIG. 3A is an example of a schematic cross-section of one implementation of a photovoltaic window with light-turning features arranged on the upper surface of the pane.

FIG. 3B is an example of a schematic cross-section of one implementation of a photovoltaic window with light-turning features arranged on the lower surface of the pane.

FIGS. 4A-B are examples of a schematic cross-section of another implementation of a photovoltaic window with light-turning features embedded within the pane.

FIGS. 5A-F are examples of a series of diagrams illustrating one implementation of a method of manufacturing frustum-shaped light-turning features.

FIGS. 6A-F are examples of a series of diagrams illustrating another implementation of a method of manufacturing frustum-shaped light-turning features.

FIGS. 7A-E are examples of a series of diagrams illustrating another implementation of a method of manufacturing a pane with multiple layers of frustum-shaped light-turning features embedded within.

FIG. 8 is an example of a flow diagram illustrating one implementation of a method of manufacturing a photovoltaic window with light-turning features.

Like reference numbers and designations in the various drawings indicate like elements.

### DETAILED DESCRIPTION

In some implementations, a power-generating window apparatus includes a partially transmissive pane and a plurality of photovoltaic cells arranged around the perimeter of the pane. A plurality of light-turning features redirect a portion of the light incident on the pane towards the photovoltaic cells arranged around the perimeter of the pane, while simultaneously permitting a portion of the light incident on the pane to be transmitted. The light-turning features can include frustum-shaped structures arranged on the light-incident surface of the pane. Alternatively or additionally, the light-turning features can include frustum-shaped cavities formed within the pane. The dimensions and arrangement of the light-turning features can be adjusted to vary the proportion of light diverted towards the photovoltaic cells, and consequently the proportion of light transmitted through the pane.

Particular implementations of the subject matter described in this disclosure can be implemented to collect light for power generation through photovoltaic cells, while simultaneously providing a functional window for ordinary use. Additionally, some implementations permit the amount of light transmitted through the window to be lowered, creating substantially the same effect of tinting a window, while putting the non-transmitted light to productive use by diverting it towards photovoltaic cells. Such windows can be used, for example, to reduce energy cost of cooling a room, both by decreasing the transmission of light through windows that carry solar energy inside the room, and by generating electricity by redirecting some of the incident light towards the photovoltaic cells.

Although certain implementations and examples are discussed herein, it is understood that the inventive subject matter extends beyond the specifically disclosed implementations to other alternative implementations and/or uses of the invention and obvious modifications and equivalents thereof. It is intended that the scope of the inventions disclosed herein should not be limited by the particular disclosed implementations. Thus, for example, in any method or process disclosed herein, the acts or operations making up the method/process may be performed in any suitable sequence and are not necessarily limited to any particular disclosed sequence. Various aspects and features of the implementations have been described where appropriate. It is to be understood that not necessarily all such aspects or features may be achieved in accordance with any particular implementation. Accordingly, it should be recognized that the various implementations may be carried out in a manner that achieves or optimizes one feature or group of features as taught herein without necessarily achieving other aspects or features as may be taught or suggested herein. The following detailed description is directed to certain specific implementations of the invention. However, the invention can be implemented in a multitude of different ways. The implementations described herein may be implemented in a wide range of devices that incorporate photovoltaic devices for conversion of optical energy into electrical current.

In this description, reference is made to the drawings wherein like parts are designated with like numerals throughout. As will be apparent from the following description, the implementations may be implemented in a variety of devices that include photovoltaic active material.

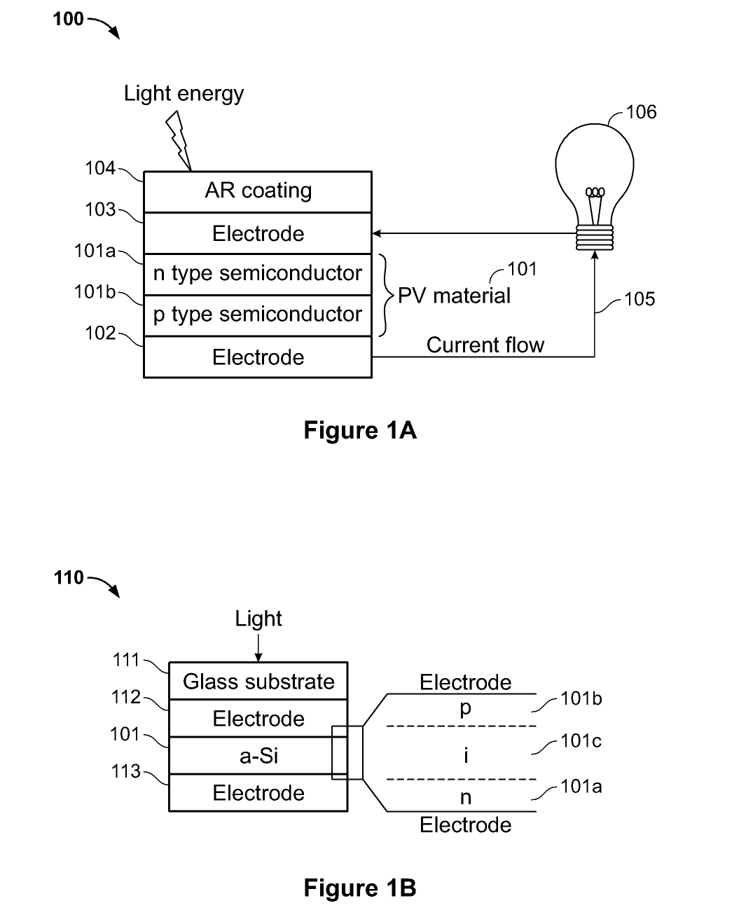

Turning now to the Figures, FIG. 1A is an example of a cross-section of one implementation of a photovoltaic cell including a p-n junction. A photovoltaic cell can convert light energy into electrical energy or current. A photovoltaic cell is an example of a renewable source of energy that has a small carbon footprint and has less impact on the environment. Using photovoltaic cells can reduce the cost of energy generation. Photovoltaic cells can have many different sizes and shapes, e.g., from smaller than a postage stamp to several inches across. Several photovoltaic cells can often be connected together to form photovoltaic cell modules up to several feet long and several feet wide. Modules, in turn, can be combined and connected to form photovoltaic arrays of different sizes and power output.

The size of an array can depend on several factors, for example, the amount of sunlight available in a particular location and the needs of the consumer. The modules of the array can include electrical connections, mounting hardware, power-conditioning equipment, and batteries that store solar energy for use when the sun is not shining. A “photovoltaic device” as used herein can be a single photovoltaic cell (including its attendant electrical connections and peripherals), a photovoltaic module, a photovoltaic array, or solar panel. A photovoltaic device can also include functionally unrelated electrical components, e.g., components that are powered by the photovoltaic cell(s).

With reference to FIG. 1A, a photovoltaic cell 100 includes a photovoltaic active layer 101 disposed between two electrodes 102 and 103. In some implementations, the photovoltaic cell 100 includes a substrate on which a stack of layers is formed. The photovoltaic active layer 101 of a photovoltaic cell 100 may include a semiconductor material, for example, silicon. In some implementations, the active layer may include a p-n junction formed by directly coupling an n-type semiconductor material 101a and a p-type semiconductor material 101b as shown in FIG. 1A. Such a p-n junction may have diode-like properties and may therefore be referred to as a photodiode structure as well.

As discussed above, the photovoltaic active layer 101 is sandwiched between two electrodes that provide an electrical current path. The back electrode 102 can be formed of aluminum, silver, or molybdenum or some other conducting material. The front electrode 103 may be designed to cover a significant portion of the front surface of the p-n junction so as to lower contact resistance and increase collection efficiency. In implementations where the front electrode 103 is formed of an opaque material, the front electrode 103 may be configured to leave openings over the front of the photovoltaic active layer 101 to allow illumination to impinge on the photovoltaic active layer 101. In some implementations, the front and back electrodes 103 and 102 can include a transparent conductor, for example, transparent conducting oxide (TCO), for example, aluminum-doped zinc oxide (ZnO:Al), fluorine-doped tin Oxide (SnO₂:F), or indium tin oxide (ITO). The TCO can provide electrical contact and conductivity and simultaneously be transparent to incident radiation, including light. In some implementations, the front electrode 103 disposed on the photovoltaic active layer 101 can include one or more optical elements (not shown) that redirect a portion of incident light. The optical elements can include, for example, diffusers, holograms, roughened interfaces, and/or diffractive optical elements including microstructures formed on various surfaces or formed within volumes. For example, roughened surface interfaces can be used to scatter light beams that pass therethrough. The scattering of light can increase the light absorbing path of the scattered light beams through the photovoltaic active layer 101 and thus increase the electrical power output of the cell 100. In some implementations, the photovoltaic cell 100 can also include an anti-reflective (AR) coating 104 disposed over the front electrode 103. The AR coating 104 can reduce the amount of light reflected from the front surface of the photovoltaic active layer 101.

When the front surface of the photovoltaic active layer 101 is illuminated, photons transfer energy to electrons in the photovoltaic active layer 101. If the energy transferred by the photons is greater than the band-gap of the semiconducting material, the electrons may have sufficient energy to enter the conduction band. An internal electric field is created with the formation of the p-n junction or p-i-n junction, which is discussed in more detail below with reference to FIG. 1B. The internal electric field operates on the energized electrons to cause these electrons to move, thereby producing a current flow in an external circuit 105. The resulting current flow can be used to power various electrical devices, for example, a light bulb 106 as shown in FIG. 1A, or to generate electricity for distribution to other devices, or to a distribution grid.

The photovoltaic active material layer 101 can be formed by any of a variety of light absorbing, photovoltaic materials, for example, microcrystalline silicon (μc-Si), amorphous silicon (a-Si), cadmium telluride (CdTe), copper indium diselenide (CIS), copper indium gallium diselenide (CIGS), light absorbing dyes and polymers, polymers dispersed with light absorbing nanoparticles, III-V semiconductors, for example, gallium arsenide (GaAs), etc. Other materials may also be used. The light absorbing material(s) where photons are absorbed and transfer energy to electrical carriers (holes and electrons) is referred to herein as the photovoltaic active layer 101 or material of the photovoltaic cell 100, and this term is meant to encompass multiple active sub-layers. The material for the photovoltaic active layer 101 can be chosen depending on the desired performance and the application of the photovoltaic cell. In implementations where there are multiple active sublayers, one or more of the sublayers can include the same or different materials.

In some arrangements, the photovoltaic cell 100 can be formed by using thin film technology. For example, in one implementation, where optical energy passes through a transparent substrate, the photovoltaic cell 100 may be formed by depositing a first or front electrode layer 103 of TCO on a substrate. The substrate layer and the transparent conductive oxide layer 103 can form a substrate stack that may be provided by a manufacturer to an entity that subsequently deposits a photovoltaic active layer 101 thereon. After the photovoltaic active layer 101 has been deposited, a second electrode layer 102 can be deposited on the layer of photovoltaic active material 101. The layers may be deposited using deposition techniques including physical vapor deposition techniques, chemical vapor deposition techniques, for example, plasma-enhanced chemical vapor deposition, and/or electro-chemical vapor deposition techniques, etc. Thin film photovoltaic cells may include amorphous, monocrystalline, or polycrystalline materials, for example, silicon, thin-film amorphous silicon, CIS, CdTe or CIGS. Thin film photovoltaic cells facilitate small device footprint and scalability of the manufacturing process.

FIG. 1B is an example of a block diagram that schematically illustrates a cross-section of one example of a photovoltaic cell including a deposited thin film photovoltaic active material. The photovoltaic cell 110 includes a glass substrate layer 111 through which light can pass. Disposed on the glass substrate 111 are a first electrode layer 112, a photovoltaic active layer 101 (shown as including amorphous silicon), and a second electrode layer 113. The first electrode layers 112 can include a transparent conducting material, for example, ITO. As illustrated, the first electrode layer 112 and the second electrode layer 113 sandwich the thin film photovoltaic active layer 101 there between. The illustrated photovoltaic active layer 101 includes an amorphous silicon layer. As is known in the art, amorphous silicon serving as a photovoltaic material may include one or more diode junctions. Furthermore, an amorphous silicon photovoltaic layer or layers may include a p-i-n junction wherein a layer of intrinsic silicon 101c is sandwiched between a p-doped layer 101b and an n-doped layer 101a. A p-i-n junction may have higher efficiency than a p-n junction. In some other implementations, the photovoltaic cell 110 can include multiple junctions.

Photovoltaic cells can include a network of conductors that are disposed on the front surface of the cells and electrically connected to the photocurrent-generating substrate material. The conductors can be electrodes formed over the photovoltaic material of a photovoltaic device (including thin film photovoltaic devices) or the conductors may be tabs (ribbons) connecting individual devices together in a module and/or array. Photons entering a photovoltaic active material generate carriers throughout the material (except in the shadowed areas under the overlying conductors). The negatively and positively charged carriers (electrons and holes respectively), once generated, can travel only a limited distance through the photovoltaic active material before the carriers are trapped by imperfections in the substrates or recombine and return to a non-charged neutral state. The network of conductive carriers can collect current over substantially the entire surface of the photovoltaic device. Carriers can be collected by relatively thin lines at relatively close spacing throughout the surface of the photovoltaic device and the combined current from these thin lines can flow through a few sparsely spaced and wider width bus lines to the edge of the photovoltaic device.

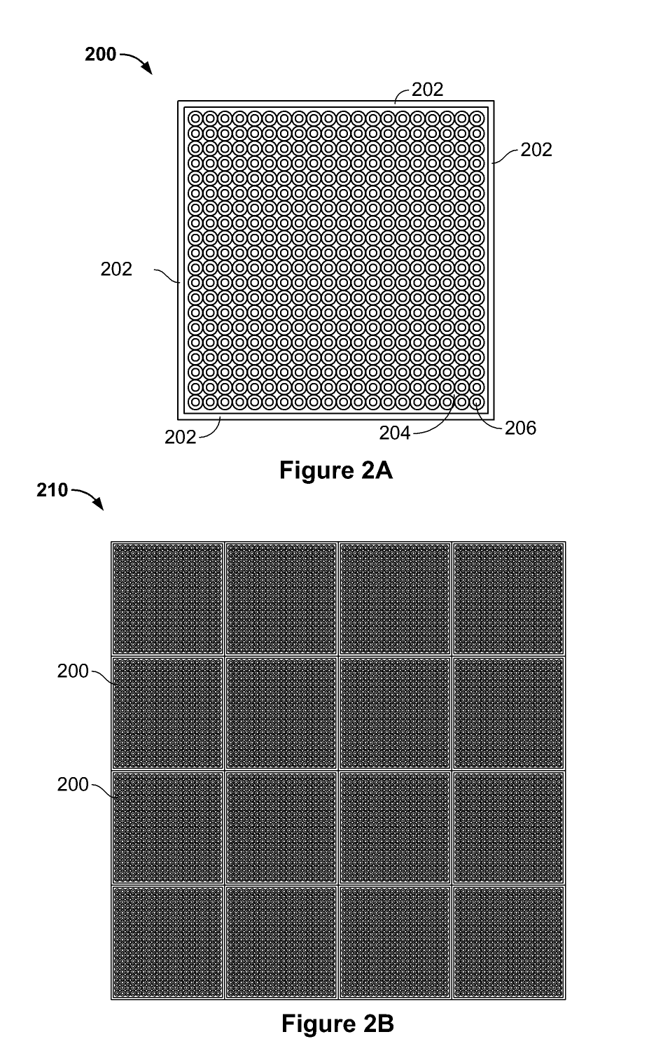

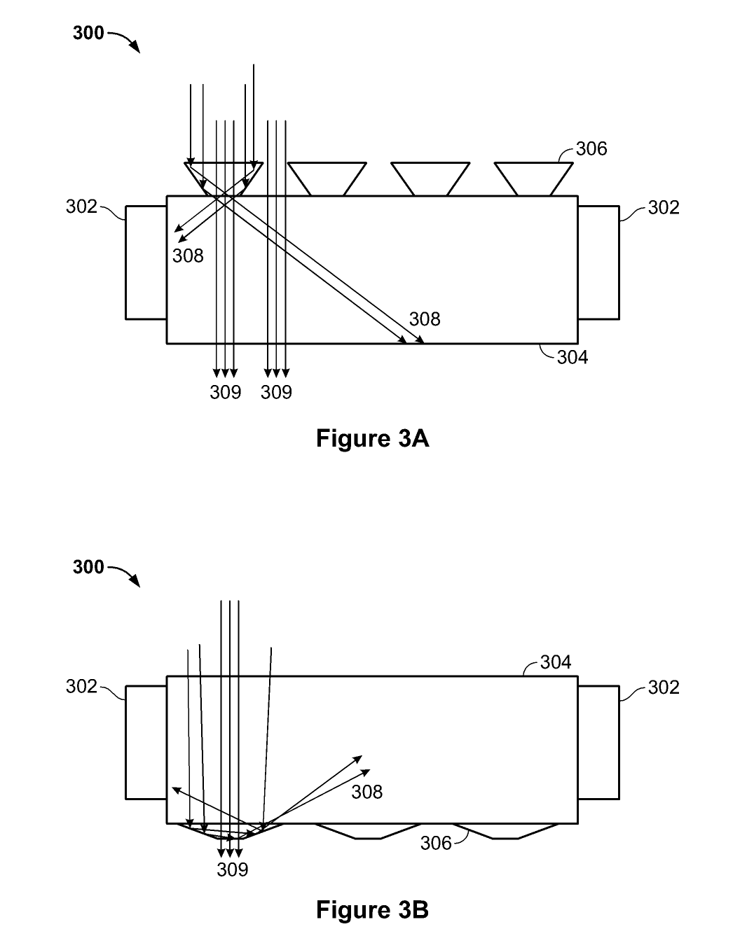

FIG. 2A is an example of a schematic plan view of a photovoltaic window. The window 200 includes photovoltaic cells 202 arranged around the perimeter of a pane 204. Light-turning features 206 are arranged within or on the surface of the pane 204 (pane 204 is also illustrated, in an example of a cross-sectional view as pane 304 in FIGS. 3A and 3B). As incident light propagates into the window 200 and strikes the light-turning features 206, at least a portion of the light is diverted towards the perimeter of the pane 204. Diverted light can propagate in any direction within the pane 204 towards the photovoltaic cells 202. The pane 204 can include glass, fiberglass, plastic, or essentially any translucent material, so long as it allows diverted light to propagate within the pane, for example, by total internal reflection in an x-direction or y-direction to the photovoltaic cells 202. Additionally, the light-turning features 206 may take any number of forms. In certain implementations of the photovoltaic window 200, the light-turning features 206 may be a series of inverted frustum-shaped structures positioned on the incident surface of the pane 204. In other implementations, the light-turning features 206 may be a series of frustum-shaped cavities within the pane, as will be discussed in more detail below.

As used herein, “frustum” can refer to a geometric shape defined by a pyramid or cone truncated by a plane substantially parallel to its base. Accordingly, a frustum-shaped object includes two substantially parallel surfaces that are connected by a tapered surface or surfaces.

FIG. 2B is an example of a schematic plan view of a tiled photovoltaic window. In the illustrated configuration, an array of photovoltaic windows 200 are arranged to create a larger, tiled photovoltaic window 210. Tiling the photovoltaic windows 200 may facilitate the efficient conversion of diverted light by photovoltaic cells. In general, the further that diverted light travels between its point of incidence on the window 200 and the photovoltaic cell 202, the more likely that it will strike another light-turning feature 206 and exit the pane 204. Referring back to FIG. 2A, as the photovoltaic window 200 is scaled, increasing proportions of light may exit the pane 204 (FIG. 2A), thereby decreasing overall efficiency. Arranging the photovoltaic windows 200 in a tiled fashion as shown in FIG. 2B may mitigate this effect, by reducing the average distance that light travels within the pane 204 before reaching one of the photovoltaic cells 202.

FIG. 3A is an example of a schematic cross-section of one implementation of a photovoltaic window with light-turning features arranged on the upper surface of the pane. As illustrated, the “upper” surface is the light-incident surface of the photovoltaic window. The window 300 includes photovoltaic cells 302 arranged at the perimeter of the pane 304. The light-turning features 306 include inverted frustum-shaped structures (a.k.a. inverted frusta) arranged on the light-incident surface of the pane 304. These inverted frusta 306 redirect a portion of the incident light towards the photovoltaic cells 302 arranged at the perimeter, while allowing some of the light to pass through the pane 304. This combination allows for the dual-functionality of the photovoltaic window as both a source of natural light and as a power-generating device. The portion of light 308 redirected towards the photovoltaic cells 302 may propagate through the pane 304 by total internal reflection, while another portion of light 309 is transmitted through the pane.

The dimensions and spacing of the frustum-shaped light-turning features 306 largely determine the proportion of light that is redirected towards the photovoltaic cells 302, and correspondingly the proportion of light that is transmitted through the pane 304. The widest point of each of the inverted frusta 306 may be between about 1 μm and about 10 mm, with the height of each inverted frusta 306 being between about 1 μm and about 5 mm. Varying these relative dimensions affects the amount of light redirected, and the amount of light transmitted through the pane 304. Depending upon the application, these dimensions may be controlled to achieve a desired proportion of diversion and transmission. For example, in certain implementations, the photovoltaic window 300 is configured to permit at least 20% of light to be transmitted. In other implementations, the photovoltaic window 300 is configured to permit at least 50% of incident light to pass therethrough. In general, the percentage of light transmitted will depend upon the “fill factor” of the frustum-shaped light-turning features. The fill factor can be defined as the surface area of the pane directly aligned with sidewalls of the frustum-shaped light-turning features divided by the total surface area of the pane. If the fill factor is 80%, then approximately 80% of incident light will be redirected towards the photovoltaic cells, while the remaining approximately 20% of the incident light will be transmitted. Similarly, if the fill factor is 50%, approximately 50% of the incident light will be redirected towards the photovoltaic cells, with the remaining approximately 50% will be transmitted. In certain implementations, the width and height of the pane are each between 0.3 meters and 3 meters. A thickness dimension of the pane 304 can be comparable to that of ordinary windows, i.e., between about 5 mm and about 5 cm.

By way of example, variations in the angle, measured with respect to a line normal to the surface of the pane, of the side walls of the inverted frustum-shaped light-turning features, may dramatically affect the proportion of light that is diverted towards photovoltaic cells. In implementations involving a 3 inch by 3 inch square pane with a thickness of 3.4 mm, with the light-turning features having a height of 100 μm, and a base width of 100 μm, the percentage of ambient light redirected towards the perimeter is approximately 20% for 20 degrees, 12% for 40 degrees, and 4% for 60 degrees. Accordingly, these parameters may be adjusted to achieve the desired proportions of redirected light and transmitted light.

The angle of the sidewalls of the frustum-shaped light-turning features 306, measured with respect to the normal, may range between about 5 to about 85 degrees. If increased re-redirection of light is desired, the angle may range between about 10 to about 40 degrees. Of course, the proportion of light redirected depends on several factors, including at least the distribution of incident light, the angles of the frustum-shaped light turning features, the thickness of the pane 304, the index of refraction of the pane 304, and the density of the frustum-shaped light-turning features 306.

FIG. 3B is an example of a schematic cross-section of one implementation of a photovoltaic window with light-turning features 306 arranged on the lower surface of the pane. As illustrated, the “lower” surface is the surface opposite the light-incident surface of the pane 304. As in FIG. 3A, the window 300 includes photovoltaic cells 302 arranged at the perimeter of the pane 304. In contrast to FIG. 3A, however, the light-turning features 306 here are frustum-shaped structures arranged on the lower surface of the pane 304, opposite the light-incident surface. These frusta 306 redirect a portion of the incident light towards the photovoltaic cells 302 arranged at the perimeter, while allowing some of the light to pass through the pane 304. This combination allows for the dual-functionality of the photovoltaic window as both a source of natural light and as a power-generating device. The portion of light 308 redirected towards the photovoltaic cells 302 may propagate through the pane 304 by total internal reflection. A portion of light 309 is transmitted through the pane without being redirected by the light-turning features 306.

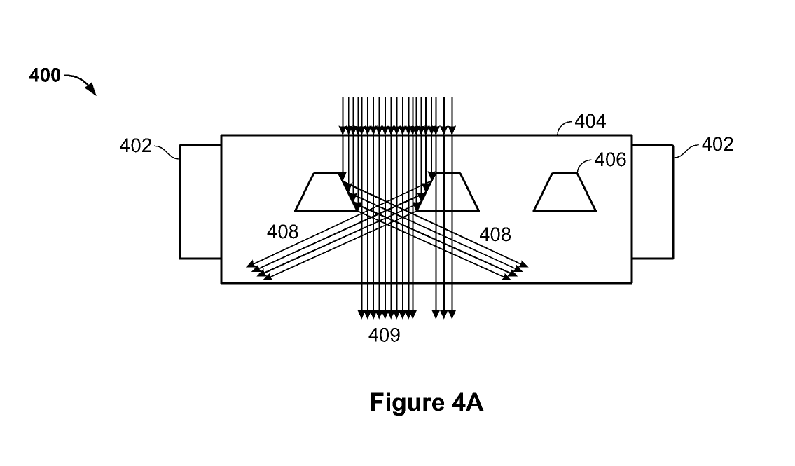

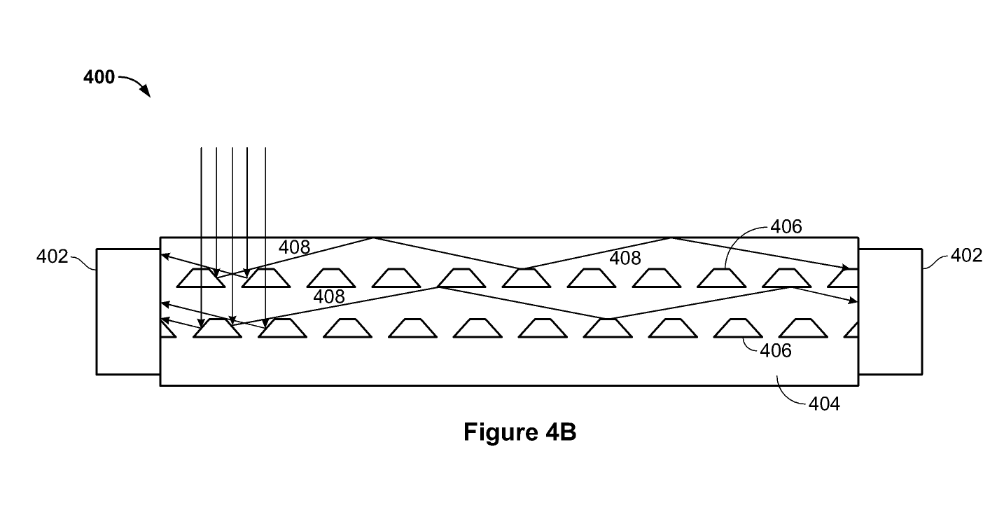

FIGS. 4A-B are examples of a schematic cross-section of another implementation of a photovoltaic window with light-turning features embedded within the pane. Similar to the implementation shown in FIGS. 3A and 3B, the photovoltaic window 400 in FIG. 4A includes a pane 404 with photovoltaic cells 402 arranged at the perimeter. Unlike FIGS. 3A and 3B, however, the light-turning features 406 are frustum-shaped air gaps embedded within the pane 404. In alternative implementations, the air gaps 406 may instead include other materials. For example, the frustum-shaped gaps may be filled with a material having an index of refraction different from air in order to vary the optical functionality of the light-turning features 406. The incident light penetrates the upper surface of the pane 404. A portion of the light 408 is reflected off the surfaces of the frustum-shaped turning features 406 and directed towards the photovoltaic cells 402 at the perimeter. Other portions of the light 409 are permitted to pass through the pane 404 completely. The portion of light 408 diverted towards the photovoltaic cell 402 may propagate within the pane 404 by total internal reflection to reach the photovoltaic cell 402 at the perimeter.

With respect to FIG. 4B, the photovoltaic window 400 includes a series of frustum-shaped cavities 406 configured to redirect a portion of light 408 towards the photovoltaic cells 402 arranged at the perimeter. In contrast to the example illustrated in FIG. 4A, however, the frustum-shaped cavities 406 are arranged in two distinct layers. The addition of a second layer of frustum-shaped cavities 406 may be employed to redirect a larger proportion of incident light towards the photovoltaic cells 402. In some implementations, arranging the layers so that the frustum-shaped cavities 406 are not vertically aligned, but rather offset from one another, results in increased redirection relative to the example illustrated in FIG. 4A. The arrangement of the layers may be adjusted to achieve a desired proportion of redirection of incident light towards photovoltaic cells 402.

As illustrated, the two layers of frustum-shaped cavities 406 are arranged are substantially identical, with only the location distinguishing the two. In other implementations, the layers may include different sized or dimensioned frustum-shaped cavities 406, different spacing between frustum-shaped cavities 406, etc. In some implementations, the dimensions of the frustum-shaped cavities 406 may vary within a single layer. In still other implementations, three or more layers may be used to achieve the desired proportion of redirection of incident light towards photovoltaic cells 402.

Similar to the discussion above with respect to FIGS. 3A and 3B, the dimensions and spacing of the frustum-shaped cavities 406 largely determine the proportion of light that is redirected towards the photovoltaic cells 402, and correspondingly the proportion of light that is transmitted through the pane 404. The widest point of each frustum-shaped cavity 406 may be between about 1 μm and 10 mm. The height of each frustum-shaped cavity 406 may be between about 1 μm and 1 millimeter. The angle of the sidewalls of the frustum-shaped cavities 406 also affects the proportion of light that is redirected towards the photovoltaic cells 402. Varying these relative dimensions affects the amount of light redirected, and the amount of light transmitted through the pane 404. Depending upon the application, these dimensions may be controlled to achieve a desired proportion of light redirection and transmission. For example, in certain implementations, the photovoltaic window 400 may be configured to permit at least about 20% of light to be transmitted. In other implementations, the photovoltaic window 400 may be configured to permit at least about 50% of incident light to pass therethrough. Similar to the discussion above with respect to FIG. 3A, the percentage of light transmitted will depend upon the “fill factor” of the frustum-shaped cavities. The fill factor can be defined as the surface area of the pane directly aligned with sidewalls of the frustum-shaped cavities divided by the total surface area of the pane. If the fill factor is 80%, then approximately 80% of incident light will be redirected towards the photovoltaic cells, while the remaining approximately 20% of the incident light will be transmitted. Similarly, if the fill factor is 50%, approximately 50% of the incident light will be redirected towards the photovoltaic cells, with the remaining approximately 50% will be transmitted. In certain implementations, the width and height of the pane are each between about 0.3 meters and about 3 meters. The thickness of the pane may be comparable to that of ordinary windows, i.e., between about 5 mm and about 5 cm.

The angle of the sidewalls of the frustum-shaped cavities 406, measured with respect to the normal, may range between about 5 to about 85 degrees. If increased re-redirection of light is desired, the angle may range between about 10 to about 40 degrees. Of course, the proportion of light redirected depends on several factors, including at least the distribution of incident light, the angles of the frustum-shaped cavities, the thickness of the pane, the index of refraction of the pane, and the density of the frustum-shaped cavities.

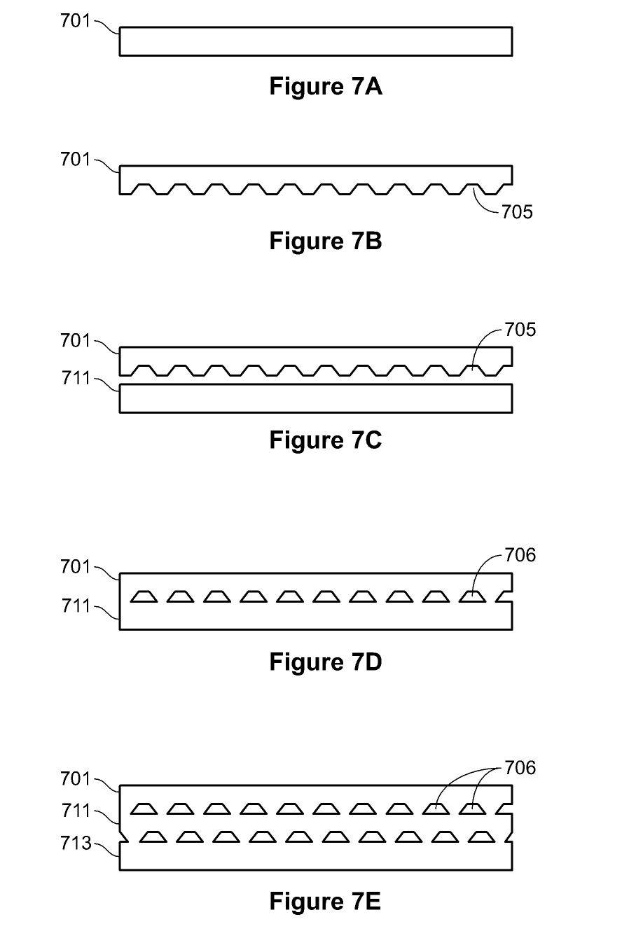

The frustum-shaped cavities 406 may be manufactured by different methods, depending on the desired size, as shown in FIGS. 7A to 7E. For cavities with widths of approximately 0.2 mm to 10 mm, the cavities may be manufactured by the use of an imprinting method. For example, a stamp may be used to press melted or soft glass at high temperatures (e.g., >600° C.). For cavities with smaller widths, for example between approximately 10 μm and 200 μm, they may be manufactured by using standard lithographic techniques. For example, wet etching or sandblast etching may be used to form the frustum-shaped cavities with relatively small dimensions.

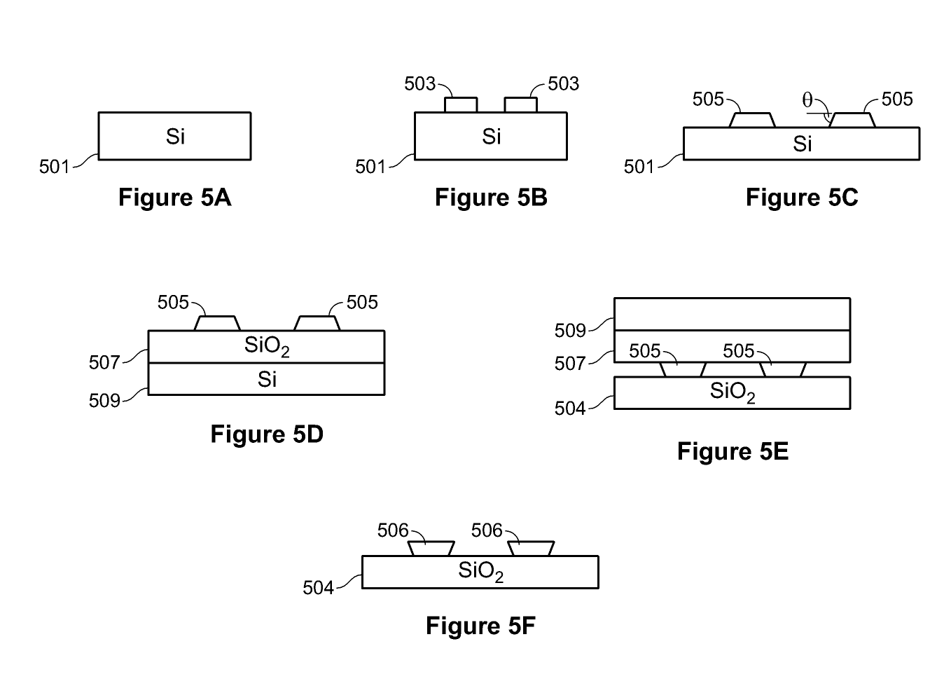

FIGS. 5A-F are examples of a series of diagrams illustrating one implementation of a method of manufacturing frustum-shaped light-turning features. In some implementations, the frustum-shaped light-turning features may have widths of between about 1 and 10 μm. FIG. 5A illustrates a crystalline silicon wafer 501. In FIG. 5B, photoresist 503 has been spun onto the surface of wafer 501 and patterned using standard lithography. In FIG. 5C, intermediate frusta 505 are formed by wet or dry etching, where the photoresist pattern has defined the frusta. The angle θ of the sidewalls of frusta 505 can be controlled, to a certain extent, by selection of etchants. The angle can be calculated as the arctangent of the ratio of the horizontal etch rate over the vertical etch rate. FIG. 5D illustrates the wafer 501, which now includes frusta 505, that has now been oxidized to silicon dioxide (SiO₂) up to a few micrometers deep. The result is an upper layer 507 of SiO₂, which includes the frusta 505, and leaving a lower layer 509 of crystalline silicon. In FIG. 5E, the structure shown in FIG. 5D is inverted and bonded to a SiO₂ substrate 504. In FIG. 5F, the lower layer 509 and the upper layer 507 are removed, leaving the substrate 504 and inverted frustum-shaped light-turning features 506.

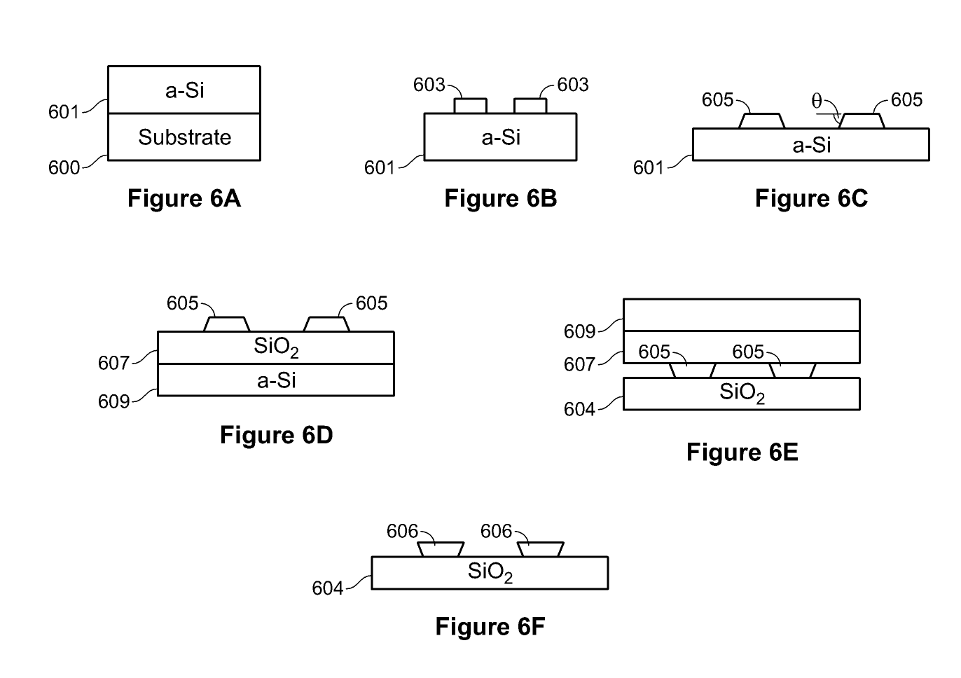

FIGS. 6A-F are examples of a series of diagrams illustrating another implementation of a method of manufacturing frustum-shaped light-turning features. In some implementations, the frustum-shaped light-turning features have widths of between about 1 and 10 μm. FIG. 6A illustrates a glass or silicon substrate 611, with a layer of a-Si 601 deposited on top of the substrate 611. The a-Si 601 may be deposited using, for example, plasma enhanced chemical vapor deposition (PECVD). In FIG. 6B, photoresist 603 has been spun onto the top surface of the amorphous silicon 501 and patterned using standard lithography. In FIG. 6C wet or dry etching is performed, with the photoresist pattern determining the area etched and, therefore, the positions of the frusta 605. Similar to FIG. 5C, discussed above, the angle θ of the sidewalls of frusta 605 can be controlled, to a certain extent, by selection of etchants. The angle can be calculated as the arctangent of the ratio of the horizontal etch rate over the vertical etch rate. The amorphous silicon 601 with intermediate frusta 605 is then oxidized up to a few micrometers deep, thereby creating an upper layer 607 of SiO₂, which includes the frusta 605, and leaving a lower layer 609 of amorphous silicon. Oxidation may be performed by wet oxygen or water (H₂O) vapor oxidization. At temperatures exceeding 1000 degrees Celsius, the bond between silicon and hydrogen breaks and SiO₂ is formed. In FIG. 6E, the structure shown in FIG. 6D is inverted and bonded to an SiO₂ substrate 604. Finally, in FIG. 6F, the unwanted structures are removed, leaving the SiO₂ substrate 604 and inverted frustum-shaped light-turning features 606. One of ordinary skill in the art will recognize from the above description that a similar technique can be used to make frustum-shaped light-turning features of different sizes.

In other implementations, the frustum-shaped structures may be formed on the top surface of the pane through a self-assembly technique. This approach may be used to fabricate frustum-shaped structures with widths ranging from about 1 to 100 μm. According to this implementation, silica frusta are fabricated by molds or other standard techniques. These silica frusta are then suspended in a colloidal suspension. The pane is then patterned using standard lithographic techniques in order to define the desired positions of the silica frusta on the pane. Next, a self-assembly technique is applied to set the array of silica frusta onto the surface of the pane.

As discussed above with respect to FIG. 4B, in certain implementations a photovoltaic window may include a pane with multiple layers of frustum-shaped cavities. FIGS. 7A-E are examples of a series of diagrams illustrating another implementation of a method of manufacturing a pane with multiple layers of frustum-shaped light-turning features embedded within. In FIG. 7A, a glass panel 701 with a flat surface is provided. In FIG. 7B, frustum-shaped recesses 705 are shaped on one surface of the glass panel 701. These recesses 705 may be formed by surface relief embossing, wet etching, sandblast etching, or any other suitable method. In FIG. 7C, another glass panel 711 is provided, and in FIG. 7D the two glass panels are bonded together by hot pressing. The bonding of these two panels creates a series of enclosed frustum-shaped cavities 706. To create an additional layer of frustum-shaped air cavities 706, another structure as illustrated in FIG. 7B may be bonded to the structure shown in 7D by hot pressing, followed by bonding of another glass panel 713, thereby creating an additional layer of frustum-shaped air cavities 706, as shown in FIG. 7E.

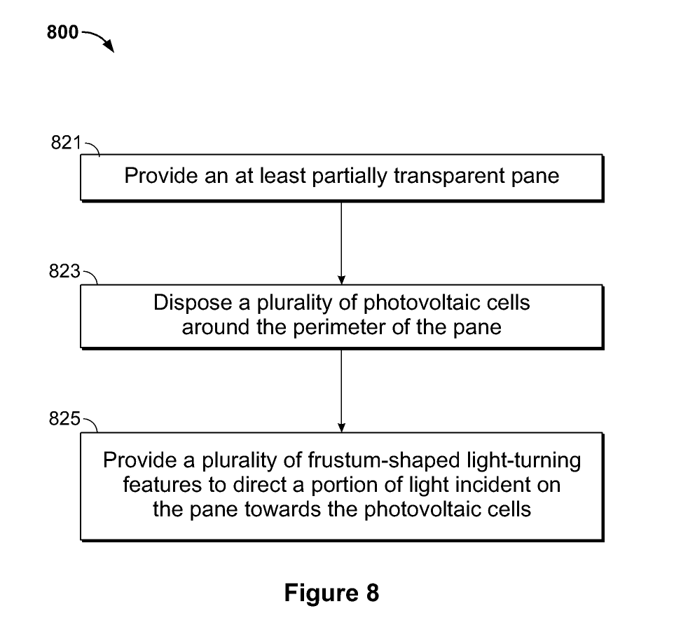

FIG. 8 is an example of a flow diagram illustrating one implementation of a method of manufacturing a photovoltaic window with light-turning features. The method 800 begins at block 821, where a partially transmissive pane is provided. As noted above, the pane may be glass, fiberglass, plastic, or essentially any translucent material, so long as it is capable of guiding light along its length. Then the method 800 transitions to block 823, where a plurality of photovoltaic cells are disposed around the perimeter of the pane. The photovoltaic cells may be optically coupled to the pane such that light propagating along the length of the partially transmissive pane is guided into the photovoltaic cells. Next, the method 800 transitions to block 825, where a plurality of frustum-shaped light-turning features are provided, on or within the pane, to direct a portion of light incident on the pane towards the photovoltaic cells. As noted above, these frustum-shaped light-turning features may include inverted frustum-shaped structures on the light-incident surface of the pane, and/or frustum-shaped cavities formed within the pane. The dimensions, spacing, and arrangement of the frustum-shaped light-turning features may be varied in order to control the percentage of incident light redirected towards the photovoltaic cells and, correspondingly, the percentage of incident light transmitted through the partially transmissive pane.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the window as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A window, comprising:
an at least partially transmissive pane, the pane including a surface for receiving incident light;
a plurality of photovoltaic cells arranged around the perimeter of the partially transmissive pane; and
a plurality of light-turning features, coupled to the pane, configured to direct a portion of light, that is incident on the surface of the pane, towards at least one of the plurality of photovoltaic cells.

2. The window of claim 1, wherein the plurality of light-turning features include frustum-shaped features arranged on the light-receiving surface of the pane, wherein each frustum-shaped feature includes a first surface and a second surface disposed substantially parallel to the first surface, the first surface having a smaller area dimension than the second surface, and wherein the first surface is disposed on the light-receiving surface of the pane.

3. The window of claim 1, wherein the plurality of light-turning features include frustum-shaped features arranged on a surface of the pane opposite the light-receiving surface, wherein each frustum-shaped feature includes a first surface and a second surface disposed substantially parallel to the first surface, the first surface having a smaller area dimension than the second surface, and wherein the second surface is disposed on the surface of the pane opposite the light-receiving surface.

4. The window of claim 1, wherein the plurality of light-turning features includes frustum-shaped cavities in the pane, wherein a portion of the pane defining each of the frustum-shaped cavities includes a first surface and a second surface disposed substantially parallel to the first surface and on an opposite side of the cavity from the first surface, the first surface having a smaller area dimension than the second surface, and wherein the first surface is disposed substantially parallel to the light-receiving surface and closer to the light-receiving surface than the second surface.

5. The window of claim 2, wherein a width dimension at the widest portion of each frustum-shaped feature is between about 1 μm and about 10 mm, and a height dimension of each frustum-shaped feature is between about 1 μm and about 5 mm.

6. The window of claim 3, wherein a width dimension at the widest portion of each frustum-shaped feature is between about 1 μm and about 10 mm, and a height dimension of each frustum-shaped feature is between about 1 μm and about 5 mm.

7. The window of claim 4, wherein a width dimension at the widest portion of each frustum-shaped cavity is between about 1 μm and about 10 mm, and a height dimension of each frustum-shaped cavity is between about 1 μm and about 5 mm.

8. The window of claim 1, wherein the plurality of light-turning features are further configured to permit at least 20% of the incident light to pass through the partially transmissive pane.

9. The window of claim 4, wherein the frustum-shaped cavities are arranged in two or more layers within the partially transmissive pane, each layer being at a different distance from the light-receiving surface of the pane.

10. The window of claim 1, wherein the pane is characterized by a width dimension and a length dimension, and wherein the width and length dimensions are between about 0.3 m and about 3 m.

11. The window of claim 1, wherein the pane is characterized by a thickness dimension of between about 5 mm and about 5 cm.

12. The window of claim 1, wherein the window is configured to direct light to propagate within the partially transmissive pane towards the plurality of photovoltaic cells by total internal reflection.

13. The window of claim 1, wherein the pane includes glass.

14. A power generating system, comprising:
a plurality of windows arranged in an array, each window including
an at least partially transmissive pane including a surface for receiving incident light;
a plurality of photovoltaic cells arranged around the perimeter of the partially transmissive pane; and
a plurality of frustum-shaped light-turning features, coupled to the pane, configured to direct light incident on the surface of the pane towards the plurality of photovoltaic cells.

15. The power generating system of claim 14, wherein each of the plurality of frustum-shaped light-turning features includes a first surface and a second surface disposed substantially parallel to the first surface, the first surface having a smaller area dimension than the second surface, and wherein the first surface is disposed on the light-receiving surface of the pane.

16. The power generating system of claim 14, wherein each of the plurality of frustum-shaped light-turning features includes a first surface and a second surface disposed substantially parallel to the first surface, the first surface having a smaller area dimension than the second surface, and wherein the second surface is disposed on a surface of the pane opposite the light-receiving surface.

17. The power generating system of claim 14, wherein each of the plurality of frustum-shaped light-turning features includes a frustum-shaped cavity in the pane, wherein a portion of the pane defining each of the frustum-shaped cavities includes a first surface and a second surface disposed substantially parallel to the first surface and on an opposite side of the cavity from the first surface, the first surface having a smaller area dimension than the second surface, and wherein the first surface is disposed substantially parallel to the light-receiving surface and closer to the light-receiving surface than the second surface.

18. A window, comprising:
a partially transmissive pane, the pane including a surface for receiving incident light;
means for generating electrical power from light, the power generating means arranged around the perimeter of the pane; and
means for redirecting a portion of light received on the light-receiving surface towards the power generating means.

19. The window of claim 18, wherein the power generating means includes at least one photovoltaic cell.

20. The window of claim 18, wherein the redirecting means includes frustum-shaped features arranged on the light-receiving surface of the pane, wherein each frustum-shaped feature includes a first surface and a second surface disposed substantially parallel to the first surface, the first surface having a smaller area dimension than the second surface, and wherein the first surface is disposed on the light-receiving surface of the pane.

21. The window of claim 18, wherein the redirecting means includes frustum-shaped features arranged on a surface of the pane opposite the light-receiving surface, wherein each frustum-shaped feature includes a first surface and a second surface disposed substantially parallel to the first surface, the first surface having a smaller area dimension than the second surface, and wherein the second surface is disposed on the surface of the pane opposite the light-receiving surface.

22. The window of claim 18, wherein the redirecting means includes frustum-shaped cavities in the pane, wherein a portion of the pane defining each of the frustum-shaped cavities include a first surface and a second surface disposed substantially parallel to the first surface and on an opposite side of the cavity from the first surface, the first surface having a smaller area dimension than the second surface, and wherein the first surface is disposed substantially parallel to the light-receiving surface and closer to the light-receiving surface than the second surface.

23. A method of manufacturing a window, the method comprising:
providing a partially transmissive pane, the pane including a surface for receiving light;
disposing a plurality of photovoltaic cells around the perimeter of the pane; and
providing a plurality of frustum-shaped light-turning features configured to direct a portion of light incident on a surface of the pane towards the photovoltaic cells.

24. The method of claim 23, wherein providing the plurality of light-turning features includes forming a plurality of frustum-shaped features on the light-receiving surface of the pane, wherein each frustum-shaped feature includes a first surface and a second surface disposed substantially parallel to the first surface, the first surface having a smaller area dimension than the second surface, and wherein the first surface is disposed on the light-receiving surface of the pane.

25. The method of claim 23, wherein providing the plurality of light-turning features includes forming a plurality of frustum-shaped features on the surface of the pane opposite the light-receiving surface, wherein each frustum-shaped feature includes a first surface and a second surface disposed substantially parallel to the first surface, the first surface having a smaller area dimension than the second surface, and wherein the second surface is disposed on the surface of the pane opposite the light-receiving surface.

26. The method of claim 23, wherein providing the plurality of light-turning features includes forming a plurality of frustum-shaped cavities within the pane, wherein a portion of the pane defining each of the frustum-shaped cavities includes a first surface and a second surface disposed substantially parallel to the first surface and on an opposite side of the cavity from the first surface, the first surface having a smaller area dimension than the second surface, and wherein the first surface is disposed substantially parallel to the light-receiving surface and closer to the light-receiving surface than the second surface.

27. The method of claim 26, wherein forming the plurality of frustum-shaped cavities within the partially transmissive pane includes
forming a first subset of the plurality of frustum-shaped cavities on a first layer within the partially transmissive pane; and
forming a second subset of the plurality of frustum-shaped cavities on a second layer within the partially transmissive pane, wherein the first and the second layers are at different distances from the light-receiving surface of the partially transmissive pane.

28. The method of claim 27, wherein forming the first subset of the plurality of frustum-shaped cavities includes forming recesses in a first glass panel, and bonding a second glass panel over the first glass panel to form frustum-shaped cavities therein; and
wherein forming the second subset of the plurality of frustum-shaped cavities includes forming recesses in the second glass panel, and bonding a third glass panel over the second glass panel to form frustum-shaped cavities therein.

29. The method of claim 28, wherein the forming recesses in the second glass panel is performed before the bonding the second glass panel over the first glass panel.

30. The method of claim 28, wherein the forming recesses in the second glass panel is performed after the bonding the second glass panel over the first glass panel.
